(19) United States
(12) Patent Application Publication
(10) Pub. No.: US 2006/0024435 A1
(43) Pub. Date: Feb. 2, 2006

(54) Turbulent mixing aerosol nanoparticle reactor and method of operating the same

(76) Inventors: Dean Holunga, Pasadena, CA (US); Richard Flagan, Pasadena, CA (US); Harry A. Atwater, South Pasadena, CA (US)

Correspondence Address: MYERS DAWES ANDRAS & SHERMAN LLP, Suite 1150, 19900 MacArthur Boulevard, Irvine, CA, 92612, US

(21) Appl. No.: 10/965,432

(22) Filed: Oct. 12, 2004

Related U.S. Application Data
(60) Provisional application No. 60/512,615, filed on Oct. 20, 2003.

(51) Int. Cl. B05D 7/00; C23C 16/00

(52) U.S. Cl. 427/212; 427/248.1; 118/715

(57) ABSTRACT

A nanoparticle reactor comprises a nucleation and core growth region providing a laminar flow of reactants in which the reactants thermally decompose to produce a supersaturated vapor that nucleates aerosol particles into particle cores. Nozzle(s) turbulently mix a preheated diluent into the heated reactants. The mixed preheated diluent and heated reactants flow into a core densification region where particle growth is quenched, coagulation limited and sufficient thermal energy for densification of the cores of the particles is provided. Nozzles turbulently mix a preheated additional reactant. A jet and chemical injection and layer formation region is used to develop the particle cores.

### RELATED APPLICATIONS

The present application is related to U.S. Provisional Patent Application, Ser. No. 60/512,626 filed on Oct. 20, 2003, which is incorporated herein by reference and to which priority is claimed pursuant to 35 USC 119.

### BACKGROUND OF THE INVENTION

1. Field of the Invention

The invention relates to the field of the manufacture of monodisperse aerosol particles for use in the fabrication of elements in optoelectronic and microelectronic devices wherein aerosol seed particles are grown to full and nearly uniform size by chemical vapor deposition (CVD). This method employs the utilization of kinetic energy from turbulent jets to mix reactants and thermal energy more efficiently and in a timescale much shorter than is possible using molecular mixing or simple turbulent pipe flow mixing.

2. Description of the Prior Art

Aerosol synthesis of nanoparticles has been the subject of numerous investigations employing the evaporation/condensation method, externally heated laminar flow reactors, laser ablation, among other methods. Control of particle size, crystallinity, and/or extent of agglomeration has been the focus of many of these investigations. But, for many applications, more complex particles are needed. Researchers have synthesized nonagglomerated nanoparticles comprised of 5-10 nm diameter single crystal silicon cores encased in silica shells. These composite nanoparticles were synthesized under clean conditions, deposited on 200 mm diameter silicon wafers, and processed through an industrial semiconductor fabrication plant to produce novel nonvolatile memory devices in which the nanoparticles served as a discontinuous floating-gate, rendering the charge retention of the memory more robust than conventional devices with a continuous floating gate. The performance of the devices synthesized by this route was very promising.

Aerosol science seeks to tailor nanoparticles for both size and composition by forming particles in a gas phase environment. Aerosol particles can be deposited on surfaces, from less than a monolayer to multilayer coverage. This provides an unparalleled advantage in the ability to exploit the unique properties of nanomaterials.

The prior art laminar flow reactors that have been the focus of much of the work to date are not well suited to the production environment. Due to the long residence times in most laminar flow reactors, particle number concentrations must be kept low to prevent runaway agglomeration. The low flow rates through laminar flow reactors, combined with the low number concentrations, lead to long deposition times. Successful incorporation of aerosol nanoparticle deposition into device fabrication will require that deposition times be competitive with conventional process steps. Higher throughput processes that maintain control over nanoparticle properties while minimizing contamination are, therefore, needed. Other nanoparticle technologies may relax the constraints on particle composition, while greatly increasing the quantities of material that must be synthesized to be technologically significant. It has been shown that increases in aerosol nanoparticle production rates are best achieved by reducing the residence time in the reactor when particles are grown by coagulation.

Laminar flow reactors in which particles grow primarily by vapor deposition produce much narrower size distributions than do reactors in which coagulation is the primary growth mechanism. Indeed, a classical method for production of “monodisperse” aerosols is the so-called Sinclair-LaMer generator in which seed particles are grown by condensation, usually a low vapor pressure organic. Similar control has been demonstrated in single-stage, laminar-flow aerosol reactors in which the seed particles are produced by homogeneous nucleation in a cool region of the reactor, where the reaction rate is relatively slow, and grown to size by gradually accelerating the reaction kinetics, usually accomplished by increasing the reaction temperature along the length of the reactor. If the rate of production of condensable product is kept low enough that the growing particles adequately scavenge those products, homogeneous nucleation can be suppressed, and narrow particle size distribution product aerosols can be synthesized. This requires precise scheduling of the reaction rate as the gases flow through the reactor to prevent runaway nucleation from producing large numbers of particles that would then grow by coagulation, forming agglomerates and broadening the particle size distribution. Combined with the low seed particle number concentrations required to suppress coagulation during growth of the seeds, this has, to date, severely limited the throughput of laminar flow reactors.

Higher number concentrations could be tolerated if reaction control were achieved much more rapidly, most likely by means other than controlling the wall temperature of a laminar tube flow, thereby facilitating higher particle production rates. Laser heating or photochemical reaction initiation, thermal plasmas, and flames can all achieve efficient precursor conversion in the short residence times needed to increase the reactor throughput, but methods that produce compound, precisely coated nanoparticles and other complex structures have not been demonstrated. Moreover, most high throughput aerosol reactors involve growth by coagulation, leading to a relatively broad particle size distribution known as the self-preserving size distribution.

### BRIEF SUMMARY OF THE INVENTION

This invention comprises an alternate approach to synthesis of narrow size distribution nanoparticles that enables higher throughput while maintaining control over particle properties, including the ability to synthesize compound nanoparticles for special applications. A two-stage version of this reactor is demonstrated in the synthesis of core/shell silicon nanoparticles with structures similar to those fabricated in Ostraat's laminar flow reactor. In the initial application of this new reactor, silicon nanoparticles are first synthesized by silane pyrolysis. An oxide shell is then produced by thermal oxidation of the outer region of the particles. The rapid heating required to carry out these reactions in a residence time as little as 25 ms for nucleation/initial growth and 10 ms for further development is achieved by turbulent mixing of a preheated carrier gas with cold precursors. The new reactor not only increases throughput, it also enhances control over the particle size distribution.

The invention is a reactor that uses turbulent kinetic energy to quickly mix cold aerosol seed particles and hot reactants and, thereby, to enable particle growth by vapor deposition in residence times much shorter than those in previous laminar flow reactors while maintaining control over particle properties, including the ability to synthesize compound nanoparticles for special applications. The illustrated embodiment shows a two-stage version of this reactor is demonstrated in the synthesis of core-shell silicon nanoparticles with structure similar to those fabricated in laminar flow reactors. In the illustrated embodiment of the reactor, silicon nanoparticles are first synthesized by silane pyrolysis. An oxide shell is then produced by thermal oxidation of the outer region of the particles. The rapid heating required to carry out these reactions, within a residence time of only 25 ms for nucleation/initial growth and 10 ms for further development, is achieved by turbulent mixing. The new reactor not only increases throughput, it also enhances control over the particle size distribution. The reactants which may be used are, however, not limited to silane, but are entirely general. Neither is the invention limited to the production of a homogeneous core within a homogeneous shell particle, nor to the method described to produce the oxide coated silicon particles. Alternate non limiting examples of particle production may also include: Heterogeneous particles of Silicon Carbide or Silicon Nitride wherein additional reactants such as ethylene or ammonia, respectively, are added into the reactor through the mixing jet, used in this configuration for dilution, to react with seed silicon particles produced by decomposition of a silicon precursor; homogeneous core particles with heterogeneous shells such as silicon cores via the route described herein and doped oxide shells such as trivalent erbium in silica. Trimethyl Gallium seeds may be produced with Arsine added in later mixers to produce Gallium Arsenide particles or Aluminum Gallium Arsenide particles with a suitably mixed aluminum precursor.

A new, turbulent flow aerosol reactor is described that enables high-throughput synthesis of uniformly-sized aerosol nanoparticles during a residence time of a few milliseconds. The short residence time allows processing of high number concentration aerosols, in excess of 10⁹ cm-3, to be processed with minimal coagulation, leading to an aerosol throughput approaching 10¹¹ particles cm⁻³s⁻¹. Turbulent mixing speeds thermal and chemical transport beyond diffusional limits inherent in laminar flow reactors, providing the thermal energy to drive chemical reactions, coalescence, densification and crystallization of particles. With enhanced transport, residence time in the reactor can be reduced, thus limiting coagulate particle growth while maintaining a high throughput of non-layered or multilayered aerosol particles.

The illustrated embodiment of the invention is a reactor for producing nano-sized particles comprising a nucleation region in which a flow of precursors react to produce a supersaturated vapor that nucleates seed aerosol particles within a limited timescale; a means or nozzle(s) for turbulently mixing a preheated diluent and/or additional reactants into the seed aerosol stream; a core densification and chemical vapor deposition (CVD) growth region in which the mixed preheated diluent and reactant(s) flow and wherein agglomerate particle growth is inhibited but additional particle growth by vapor deposition is enhanced with sufficient thermal energy provided for densification of the particles; means or nozzle(s) for turbulently mixing preheated additional reactant(s); and a mixing jet(s) for chemical injection and layer formation region(s) for developing particles beyond the core. While nozzles are contemplated as the preferred means for turbulently mixing, any other type of mechanism or structure which causes turbulent mixing as a method superior to both molecular diffusion and pipe flow turbulent mixing, which is now known or later devised, may be equivalently substituted.

The average residence time in the nucleation and seed region is of necessity maintained below the characteristic agglomeration time for the number and size of particles desired. Particle seeds are formed by reaction of precursors leading to a supersaturation of (low) vapor pressure elements and leads to nucleation and seed particle formation in the nucleation region. In this form of the reactor, thermal energy is employed, but this method is not limiting. Other methods, including reactions that are laser induced, chemically induced, plasma induced or vapor pressure induced are listed herein as nonlimiting examples of alternate methods for providing reaction energy producing the supersaturation of precursors necessary for nucleation.

The means or nozzle(s) for turbulently mixing a preheated diluent into the heated reactants comprises means or nozzle(s)for diluting particle concentration approximately one order of magnitude or greater to reduce characteristic agglomeration times by the corresponding inverse of the magnitude of the dilution while suppressing further nucleation of seed particles and continuing particle growth by CVD.

The means or nozzle(s) for turbulently mixing a preheated diluent into the heated reactants comprises means or nozzle(s) for temporarily maintaining the particles distribution approximately fixed while densification of the particles occurs. For compound particles, additional energy contributes to enhancement of internal diffusion and the production of a heterogeneous particle.

One or more nozzles inject the diluent with sufficient kinetic energy for jet flow turbulence velocities (Re>30) to provide rapid thermal and chemical equilibrium within a path length in the core densification region on the order of the core densification region diameter. Preferably at least two nozzles are used and located opposite each other across the reactor.

Reactions are performed in the during and after the chemical injection and may consume particles from the surface inward, wherein mass and size added to the particle core, or prepare the surface of the particle for further reaction(s). In one embodiment, the surface of the particle may be prepared in the from reactants introduced through the first jets by adding a wetting compound and the layer formation following the second jet using a non-wetting reactant.

The means or nozzle(s) for turbulently mixing a preheated additional reactant through the jet to the chemical injection and layer formation region comprises means or nozzle(s) for using turbulent mixing to ensure proper pretreatment of surfaces or reaction ignition within a path length of the reactor diameter.

The reactor in one embodiment may further comprise a porous or perforated tube located radially around a nucleation zone in the nucleation region for introducing a preheated diluent to both initiate reactions and reduce precursor loss. The porous or perforated tube is arranged and configured to create a pressure wall which envelops axial flow of the heated reactants in the nucleation region and to accelerate the axial flow to reduce the residence time of the seed nanoparticles. The porous or perforated tube may limit the precursor loss entirely to diffusional losses against an incoming flow. The porous or perforated tube introduces a preheated diluent through a porosity of the tube of a size such that the diluent passes uniformly into the nucleation and core growth region.

The reactor may still further comprise means for confining reactor flow through a coaxial outer annular flow to reduce precursor loss. The means for confining reactor flow through a coaxial outer annular flow to reduce precursor loss comprises a means for introducing a preheated concurrent laminar stream in the nucleation region at the same average velocity as the precursor containing stream, which introduction limits precursor loss to that which can diffuse across the confinement flow, and/or which flows the two streams concurrently for less time than the characteristic diffusion time across the annular flow before being first turbulently mixed.

The reactor may further comprise means or nozzles for sequentially turbulently mixing a plurality of preheated additional reactants into a corresponding plurality of jet and chemical injection and layer formation regions and for developing the particles in each of the plurality of jet and chemical injection and layer formation regions. The means or nozzles for turbulently mixing a plurality preheated additional reactants prevent back diffusion of reactants into upstream portions of preceding ones of the plurality of jet and chemical injection and layer formation regions where particles are still developing.

The invention also includes within its scope a method of operation of the above disclosed reactor embodiments.

While the apparatus and method has or will be described for the sake of grammatical fluidity with functional explanations, it is to be expressly understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112 are to be accorded full statutory equivalents under 35 USC 112. The invention can be better visualized by turning now to the following drawings wherein like elements are referenced by like numerals.

### BRIEF DESCRIPTION OF THE DRAWINGS

FIG. 1 is a simplified diagram of a turbulent reactor devised according to the invention.

FIG. 2 is a graph showing the effect of varying flow ratios and number of jets on relative jet diameter to maintain jet powered mixing.

FIG. 3 is a schematic diagram of a three-dimensional reactor/furnace grid used in computational fluid dynamics modeling.

FIG. 4 is a computed data graph of velocity contours for 10:1 flow rate 180 sccm of precursor, 1800 sccm nitrogen diluent, and 400 sccm oxidant in the model of FIG. 3.

FIG. 5 is a computed data graph of temperature contours for 10:1 flow rate 180 sccm of precursor, 1800 sccm nitrogen diluent, and 400 sccm oxidant in the model of FIG. 3.

FIG. 6 is a computed data graph of pressure contours for 10:1 flow rate 180 sccm of precursor, 1800 sccm nitrogen diluent, and 400 sccm oxidant in the model of FIG. 3.

FIG. 7a is a bright field and FIG. 7b is a dark field TEM Image of 10 nm oxide coated silicon nanoparticles. Crystallinity of the majority of particles is confirmed by dark field image.

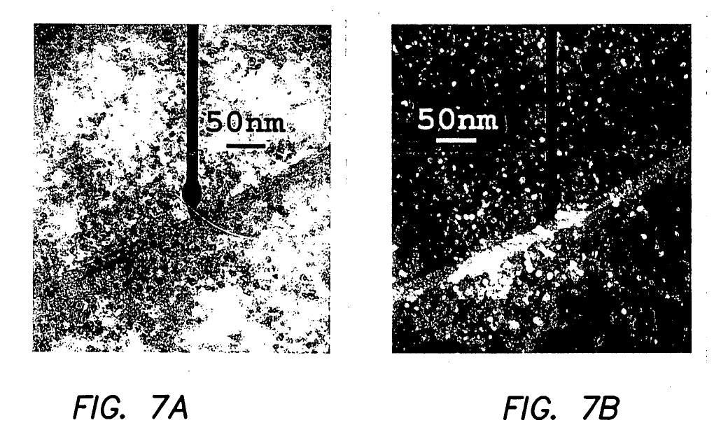

FIG. 8 is a photographic diffraction pattern of 10 nm particles seen in FIGS. 4-6.

FIG. 9a is a HRTEM Image of 10 nm oxide coated silicon particles from FIG. 4. Particles were agglomerated into fractal-like whiskers and not suitable for HRTEM.

FIG. 9b is a HRTEM Image of 10 nm oxide coated Silicon particles collected at reduced density.

FIG. 10 is a TEM Image of 10 nm particles collected by electrostatic precipitation on holey carbon grid. Note uniformity of size and occasional grouping of particles in close-packed structures. The inset is SAD diffraction pattern from randomly oriented nanocrystalline silicon.

FIG. 11 is a photograph of reactor fouling on quartz tubing.

FIG. 12 is a photograph showing the effect on measured particle distribution of varying quenching flow ratio on particle distribution for 150 ppm SiH₄ in 270 sccm N₂. Normalized trace on the right shows relative effect on distribution.

FIG. 13 is a graph of a curve fitted to left mode of a particle distribution with geometric mean of 1.1. Decreasing precursor concentration removes the right mode.

FIG. 14 is a graph which shows the shift in size distributions of particles characterized by radial DMA as precursor concentration is varied. The second mode in the 100 ppm trace is likely the rise of doublet particles. At 150 ppm, agglomeration of particles is overwhelming the monodispersity of the distribution.

FIG. 15 is a graph which shows the decrease in size and numbers of silicon particles as reactor fouls.

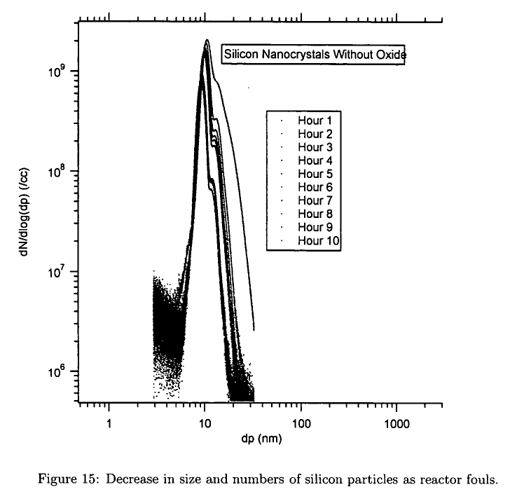

FIG. 16 is a graph which shows the decrease in size and numbers of oxide coated silicon particles as reactor fouls.

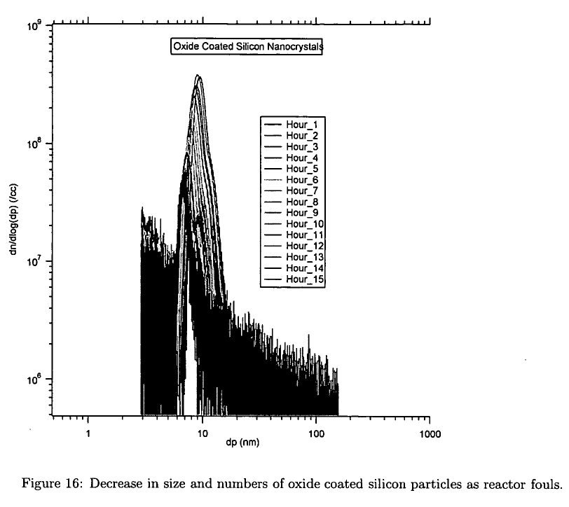

FIG. 17 is a graph which shows the size of particles produced using a ⅛″ OD inlet tubing.

FIG. 18 is a graph which shows the current read by electrometer (fA) of non-neutralized nanoparticles with radial DMA operated in scanning mode.

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

### DETAILED DESCRIPTION OF THE PREFERRED EMBODIMENTS

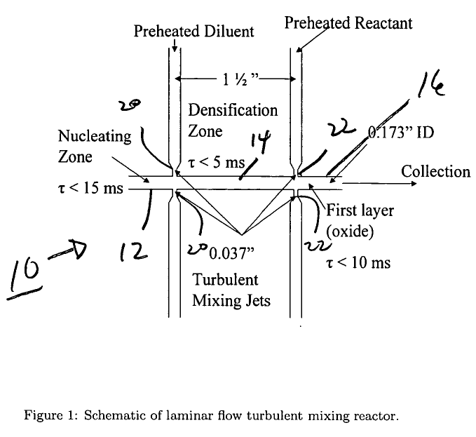

The manufacture of monodisperse aerosol particles in milliseconds at particle densities of 10⁹ particles per cubic centimeter and higher is possible using a new class of reactors, generally denoted by reference numeral 10 in FIG. 1, utilizing turbulent mixing. Turbulent mixing enhances thermal and chemical transport above what is available in prior art laminar flow reactors, providing thermal energy or additional reactant species to drive reactions while conserving residence time in the reactor 10, thus limiting coagulate particle growth. The particles produced are highly uniform in both size and composition. This reactor class 10 also lends itself to high throughput production of heterogeneous particles and multilayered homogeneous and heterogeneous aerosol particles. The turbulent mixing reactor 10 addresses the need for higher throughput reactors.

Consider first some principles regarding turbulent mixing as determined by the invention. It has been observed that flow from a narrow diameter jet into a large quiescent volume deviates from laminar flow with Re>30. A turbulent mixer may be produced when relatively fast moving fluid is introduced normally through small-diameter jets into a relatively slowly moving flow stream. With sufficient kinetic energy, jets will fully mix with the axial flow within a path length on the order of the mixing channel diameter. In a relatively long reactor, thermal and concentration fluctuations decay on a timescale much less than the residence time. For submicron particles, turbulence has little effect on agglomeration. Multiple turbulent mixing jets in series provide a physical means for producing multilayered onion-skin particles.

Tubular aerosol reactors are limited in operation by three mechanisms, each of which can be described by a respective time constant. These are the characteristic times of agglomeration (Tₐ), densification (T_{d}) and mixing (Tₘ). Accurate predictions of Tₐ are obtained from established models. But for T_{d}, no single two particle sintering model exists that fully describes the fusing and densification of two particles into a single crystal particle. Further understanding of the mechanisms involved would lead to better optimization of aerosol reactors.

The fast turbulent mixing reactor of the invention is comprises of three zones or regions 12, 14 and 16 partitioned by two pairs of quick mixing jets 20 and 22 as diagrammatically depicted in FIG. 1. In the illustrated embodiment the first region 12 is for preheating to induce thermal decomposition of silane and nucleate silicon particles. The second region 14 enables particle sintering and densification using preheated nitrogen as both a diluent and thermal well. The thermal oxide is grown in the third reactor region 16. The timescale for mixing in laminar flow greatly exceeds the timescale of agglomeration for a large number of particles.

A discussion below of Tₐ and Tₜ will discuss semi-quantitatively the need for an enhanced transport reactor. It has been shown that concentration fluctuations in mixing fluids can decay within the same length scale as the dissipation of turbulence. For isotropic or nearly isotropic fluids, a characteristic time for mixing as:
Tₘ=3.3 (ML²I P)^{1/3}

where M is the mass of fluid in the dissipation region, P is the power supplied by a mixer and L the integral dimension of mixing. In this reactor, power is supplied by the momentum of the mixing fluids and L is assumed equivalent to the diameter of the tubing, dₜ. The kinetic energy of the impinging jets is dissipated as turbulence to mix the gas flows rapidly.

For an aerosol flow stream of flow rate Qₒ mixed by total flow rate Qⱼ where Qⱼ is equally divided into fraction φ entering through 1/φ jets of diameter dⱼ, the characteristic mixing parameter is found to be:

$$3.3 ( \frac{\frac{1}{32} {π}^{2} {d}_{t}^{2} {L}^{3}}{\frac{{Q}_{0}^{3}}{{d}_{t}^{4}} + \frac{{Q}_{j}^{3} {φ}^{2}}{{d}_{j}^{4}}} )$$

When most of the turbulent mixing power is supplied through the jets, e.g. Qⱼ>>Qₒ, then Tₘ varies as:

$${( 2 {( \frac{{d}_{j}}{{d}_{t}} )}^{4} ( \frac{1}{{φ}^{2}} ) )}^{\frac{1}{3}}$$

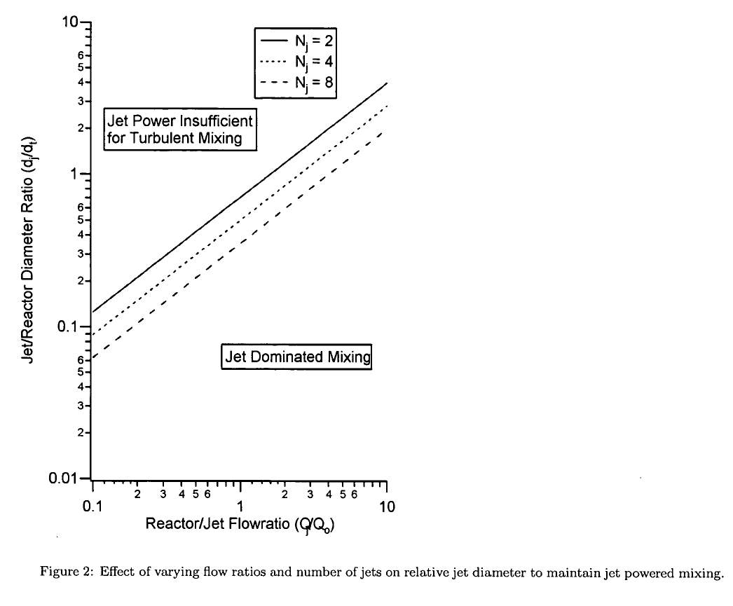

When jet power dominates mixing power, concentration and thermal fluctuations quickly decay. FIG. 2 is a graph which shows the effect on dⱼ dₜ for varying reactor/mixing flow ratios Qⱼ/Qₒ and number of jets Nⱼ. Two trends are observed. First, as the ratio of Qⱼ/Qₒ decreases, as inevitably must happen with subsequent downstream mixers in multilayer particle production, dⱼ/dₜ must decrease to provide sufficient mixing power. Second, if the number of jets, Nⱼ, is increased, so also must dⱼ decrease, but it is not linear with Nⱼ.

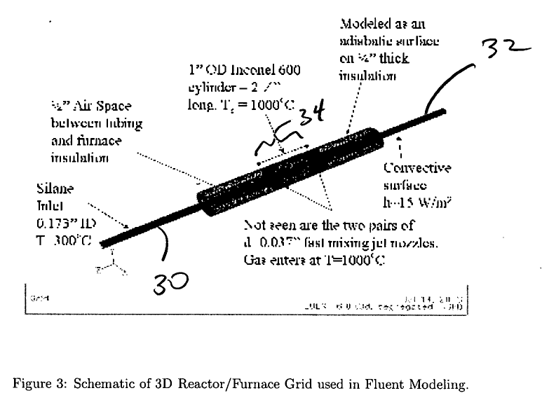

The reactor 10 was mathematically modeled in three dimensions using computational fluid dynamics to provide a basis of the steady state thermal and flow characteristics. The solver was the standard K-ε model which accounted for the turbulent mixing regions. The reactor 10 was modeled as a three dimensions cylinder as diagrammatically shown in FIG. 3 was that comprised the entrance/exit tubing 30 and 32 with convection to the atmosphere, a cut-section 34 of the insulated preheating/cooling zones and the reactor 10 with two pairs of concentric mixing jets. The reactor surface, quenching nitrogen streams and reactant oxygen streams were assumed to enter at 1000° C. The surface of the cut section 34 of the insulated box furnace's radial walls were assumed to be adiabatic but axial thermal transport was coupled within the solver. Convection to the incoming and outgoing tubing 30 and 32 was described using a convection coefficient of 15 W m2K with T1 at 300K. Incoming reactant entered at room temperature (300K) and the exit pressure was atmospheric.

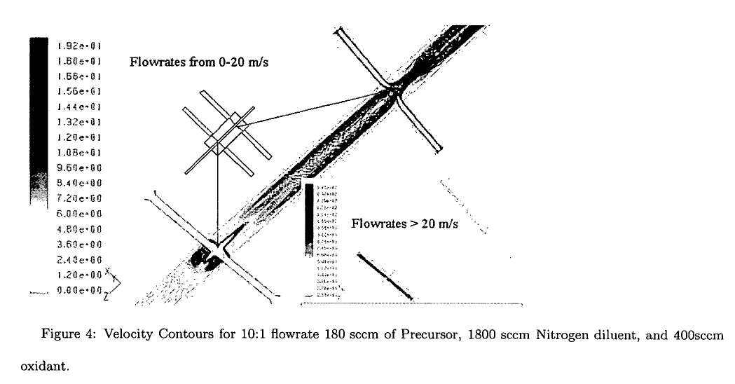

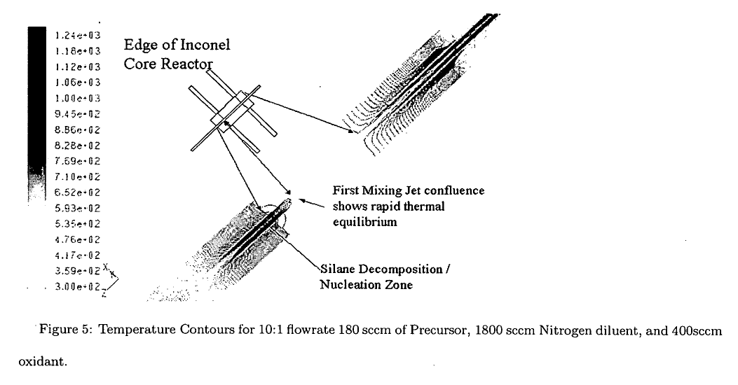

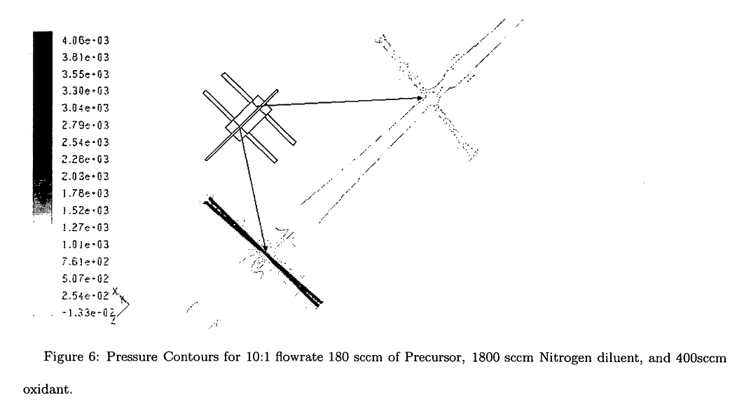

FIGS. 4-6 are data graphs of the model which show representative temperature, pressure and velocity contours for operation with 2400 sccm total flow (180 sccm nucleation flow, 1800 sccm quenching flow and 400 sccm oxidizing flow) at a 10:1 dilution flow rate. FIG. 5 indicates quick thermal equilibrium in the mixing jet zone. Since the ratio of thermal diffusivity to molecular diffusivity, α/D is of about O(1), the modeled decay of thermal fluctuations from mixing is similar to the decay of concentration fluctuations. The pressure contour plot is included in FIG. 6 to show model convergence.

For equally sized free-molecular particles, the characteristic time for coagulation is given as: T_{c}=2/(NₚK) where Nₚ is the number of particles per unit volume and K is the Brownian coagulation rate coefficient.

$$K = 4 {( \frac{6 kT}{{ρ}_{p}} )}^{\frac{1}{2}} {D}_{p}^{\frac{1}{2}}$$

If a production rate of 10⁹ particles/cm³ is desired, then Tₐ within a 1000° C. reactor is of about O(0.6 s). In this reactor 10, nucleation occurs before a 10:1 dilution, limiting the residence time for nucleation and initial growth to about O(0.05 s). Initial coalescence is defined where a mechanism of surface diffusion initiates fusing of silicon nanoparticles. The characteristic time for neck growth, (Tₛ), using the classical sintering model is:

$${τ}_{s} = \frac{{a}_{m}}{B ( T )} = \frac{{a}_{m}}{{AT}^{γ}} {ⅇ}^{\frac{E}{RT}}$$

Further densification can be characterized by grain-boundary diffusion using a surface area based linear rate law. This time constant, T_{f}, is:

$$\frac{ⅆ {a}_{p}}{ⅆ t} = - \frac{1}{{τ}_{f}} ( {a}_{p} - {a}_{sph} )$$

where aₚ is the surface area of an initially necked biparticle and aₛₚₕ the surface area of the final coalesced single particle. Estimating T_{f} from an isothermal process overestimates the time of actual exothermic coalescence.

$${τ}_{f} = \frac{3 {k}_{B} {T}_{p} N}{64 π {σ}_{s} {D}_{eff}}$$

where k_{B} is the Boltzmann constant, Tₚ is the temperature of the system, N is the number of silicon atoms comprising the coalescing sphere, σₛ is the bulk silicon solid state surface tension and D_{GB} is the solid-state grain boundary diffusion coefficient D_{eff}=D_{GB}(δ/dₚ) with δ being the grain-boundary width, dₚ the small particle diameter and the diffusion coefficient having an Arrhenius behavior D_{GB}=Ae^{-B/Tp}. The time required for two 8 nm particles to coalesce into 10 nm particle is of about O(μs). In order to ensure that the coalesced particle forms a single crystal, an approximate O(ms) residence time is provided to allow annealing within the reactor.

Each of the two sintering processes examined above yield characteristic time constants less than 100 μs, sufficiently less than both the agglomeration time constant and characteristic time for diffusional mass transfer across a 0.5 cm radius tubular laminar flow reactor.

Return now again to a diagrammatic consideration of an illustrative experimental embodiment of the invention in FIG. 1. The reactor 10 of the invention is comprised of three general functional regions 12, 14 and 16, some of which may be repeated for the production of multilayered particles, if desired. First there is a nucleation and core growth region 12 shown in FIG. 1. In this region, reactants are heated to thermal decomposition temperature to produce a supersaturated vapor that nucleates aerosol particles. The flow regime is laminar and the average residence time must be kept below the characteristic agglomeration time for the number and size of particles desired. Particle growth can occur by chemical vapor deposition at the surface of particles, or by particle-to-particle collision (agglomeration). However, densification of particles is limited by the lack of thermal energy.

Second there is a core densification region 14. This region quenches particle growth, limits coagulation and provides sufficient thermal energy for densification of the core of the particle. Densification time for sub-15 nm particles is not well predicted, but appears to still be less than the characteristic agglomeration times for densities of 10⁹ particles/cm³. By diluting the flow to reduce the particle concentration approximately one order of magnitude or greater, characteristic agglomeration times are reduced by the corresponding inverse of the dilution. Hence the particles distribution can be temporarily “frozen” while densification occurs. However, the time scale for thermal diffusion in a gas is much too slow to ensure proper densification before agglomeration begins to dominate particle growth again. The use of preheated diluent 18 that is injected through nozzle(s) 20 where the gas reaches turbulent velocities (Re>2300) provides rapid thermal and chemical equilibrium within a path length in densification zone 14 on the order of the reactor diameter. The greater the number of nozzles 20, the quicker mixing is accomplished.

Two nozzles 20 located opposite each other across the reactor 10 as shown in FIG. 1 provide the minimum action for a well-mixed system. The length of densification zone 14 is on the order of 5-10 reactor diameters to allow eddies formed from turbulent mixing effects to dampen if desired.

A third region is a mixing jet and chemical injection region and layer formation region, denoted by reference numeral 16 in FIG. 1. This region 16 may be repeated if desired for multilayered particles. Nozzles 22 for turbulent mixing jets introduce new chemical species to further particle development. Reactions may consume particles from the surface inward, or add mass and size to the particle core. Added components may simply prepare the surface for further reactions (e.g.: adding a wetting component for a non-wetting reactant.) Turbulent mixing jets 22 ensure proper pretreatment of surfaces or reaction ignition within a path length in region 16 on the order of the reactor diameter.

The nucleation and core growth region 12 is subject to particle and precursor loss to the walls of the reactor 10. The Peclet number for mass transport becomes increasingly unfavorable as both the temperature is increased and reactor diameter decrease. The Péclet number is a dimensionless parameter of a system defined by

$$\begin{matrix}Pe ≡ \frac{[ advection of heat ]}{[ conduction of heat ]} & ( 1 ) \\ = \frac{\vert u \cdot ∇ T \vert}{\vert κ {∇}^{2} T \vert} = \frac{U L}{κ} , & ( 2 )\end{matrix}$$

where u is the flow velocity, T is the temperature, U is the velocity scale, L is the length scale, and κ is the thermal diffusivity

To reduce this loss, design changes may include the introduction of a preheated diluent through a porous tube (not shown) located radially around the nucleation zone 12. A pressure wall envelops the axial flow and subsequent acceleration of fluid reduces the residence time of the developing nanoparticles. Precursor loss is limited entirely to diffusional losses against the incoming flow. The porosity of the tube must be of a small size such that the diluent passes uniformly into the reactor 10.

Loss reduction may also be realized by reactor flow confinement through a coaxial outer annular flow. For example, a second, preheated concurrent laminar stream (not shown) is brought in zone 12 at the same average velocity as the precursor containing stream, which introduction limits precursor loss to that which can diffuse across the confinement flow. If the two streams flow concurrently for less time than the characteristic diffusion time across the annular flow before reaching the first turbulent mixing jet 20, precursor and small particle loss is strongly limited.

Another improvement comprises the employment of a nozzle type jet (not shown) in front of turbulent mixers 10 between consecutive reaction zones 16 for the purpose of preventing back diffusion of reactants into portions of regions 12, 14 or 16 where layers are still developing.

It has previously been demonstrated in the art that an 80% monolayer of silicon nanocrystals functioned as an effective floating gate for a traditional electrically switched nonvolatile memory device. These prior art studies were performed on 200 mm wafers where deposition times were 6-8 hours and wafer coverage ranged from monolayer near the center to about 10% monolayer at the edge. In contrast, in the present invention we seek to provide uniform near-monolayer coverage on 300 mm wafers over a similar deposition time. This requires a minimum ten-fold increase in the number of particles deposited.

Consider now a specific embodiment of the invention in which silane is pyrolytically decomposed to produce Si nanoparticles that are then partially oxidized to produce an SiO₂ coating over an Si core. Dilute SiH₄ in nitrogen at parts per million concentration is introduced into the tubular reactor via a ¼″ OD Inconel 600 tube 30. The precursor is heated as it passes within the tubing 30 through an insulated wall of a box furnace (not shown) internally maintained at 1000° C., thermally decomposing part of the silane and driving silicon nucleation with the supersaturated vapor. One of two growth mechanisms may dominate further particle evolution. If nucleated particle concentration is sufficiently low, then growth may proceed by vapor deposition as additional silane reacts, leading to a narrow size distribution. If, however, nucleation produces too many particles, growth by agglomeration dominates leading to a relatively broad self-preserving size distribution.

Downstream from the nucleation zone, the particles and remaining reactant enter the hot zone of the furnace (not shown). Preheated nitrogen at 1000° C. is introduced from two opposing radial positions at high velocities via small diameter tubing 22. The rapid mixing with the hot diluent heats the reactants to sufficiently high temperature to drive the reaction to completion. The resulting sudden dilution also reduces or quenches the coagulation and provides thermal energy for coalescence and densification. Thorough mixing of the particle stream and nitrogen streams is accomplished within a length scale that is the order of the diameter of the reactor or tubing 30. While coalescence for sub-10 nm particles is predicted to be on the order of microseconds, the time for crystallization is not known and milliseconds are provided to anneal the particles.

To enable long term charge storage within the nanocrystal in a memory device application, a silicon oxide layer is grown on the outer surface of the particle. A flow of pure oxygen that has been preheated to 1000° C. is introduced through a second pair of opposed mixing jets 22 in a second turbulent mixing zone 16. Oxygen diffuses to and through the surface, oxidizing the silicon and shrinking the core of the nanoparticle while creating the oxide shell. For a low defect well-passivated oxide, the concentration of O₂ is kept above 15%.

The particle stream exits the furnace and is cooled by convection to room temperature (300K). A portion of the stream is diluted, using a turbulent mixer, with nitrogen gas exiting a TSI Model 3077 85Kr neutralizer, in which an ambipolar ion mixture has been produced by exposure to ionizing radiation from a sealed capsule of 85Kr in a so-called neutralizer, at a dilution ratio greater than 5:1. A neutralizer is used to impart a well-characterized steady state charge distribution on particles to enable differential mobility analysis. The mixture is characterized by a radial DMA operated in scanning mode and an femtoampere resolution electrometer to provide a continuous online measurement of the particle distribution. A scanning mode algorithm is based a conventional de-smearing method. The remainder of the aerosol stream is available for collection by either electrical or thermophoretic precipitation. Particles can be deposited on a variety of substrates including Si and Ge wafer fragments or TEM grids. Further particle characterization was performed on a Philips 420 transmission electron microscope.

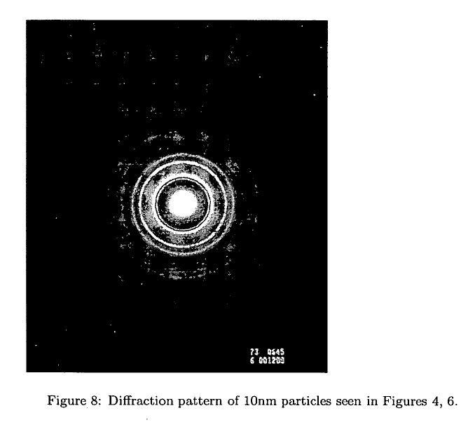

Particle concentrations as high as 10⁹/cm³ were recorded with mean size of 10-12 nm and a geometric mean of 1.25. Greater monodispersity (σ_{g} of 1.1) is seen at concentrations as high as 5×10⁸/cm³. TEM analysis of particles grown with a thermally oxidized shell shows that particles are spherical, have crystalline silicon cores of 4-6 nm and an amorphous oxide layer of thickness 2-3 nm. Particles imaged by TEM demonstrate a diffraction pattern characteristic of silicon, and show strong luminosity under dark field illumination. High resolution TEM (HRTEM) images of particles show characteristic lattice fringes in the core region, further evidence for crystallinity and core size. TEM images of oxide coated silicon particles are shown in FIGS. 8-11.

In FIG. 8, particles collected by electrostatic precipitation on a holey carbon TEM grid are shown. These corresponding bright field and dark field images were taken at a magnification of 200K. The intensity of the dark field image, resulting from diffraction of the electron beam off crystal planes, reveals that particles are similar in their morphology. Narrowness of the distribution, as measured with the DMA, is also qualitatively confirmed in these images.

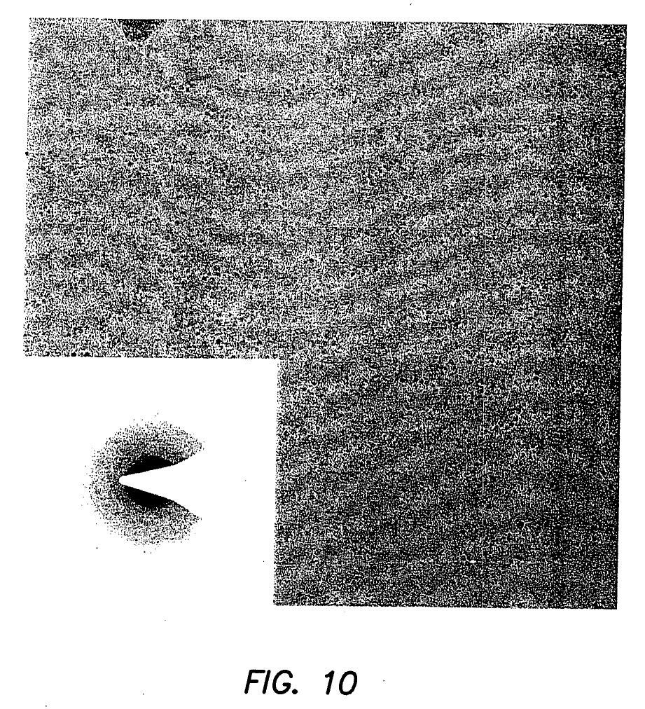

In FIG. 10a, HRTEM images at 550K shows several cold agglomerated particles with a crystalline core of 4-6 nm and a non-crystalline shell of 2-3 nm. The thickness of the shell is consistently sized with a thermally grown oxide layer, not a native oxide. With HRTEM, particles must be in a correct orientation (e.g.: near the [111] plane for silicon) for lattice fringes from crystals to be seen, thus randomly oriented particles may or may not show lattice fringes. But diffraction intensity seen in the dark field image reveals that most, if not all, particles possess a crystalline core.

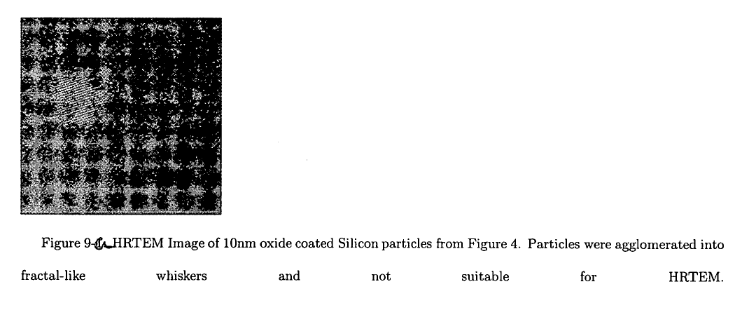

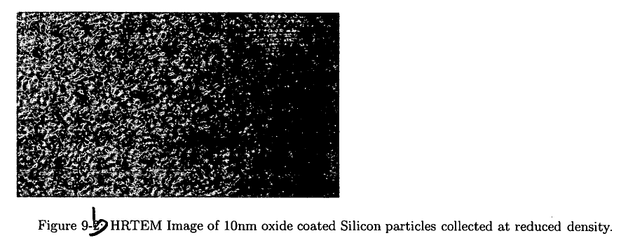

FIG. 9 shows a diffraction pattern of these particles using a SAD aperture of 20 μm. The presence of multiple spots in a ring-forming pattern confirm that the particles are crystalline and randomly oriented on the grid surface. FIG. 10b shows an HRTEM image of particles collected at a much lower number density where the lattice fringes are more clearly visible.

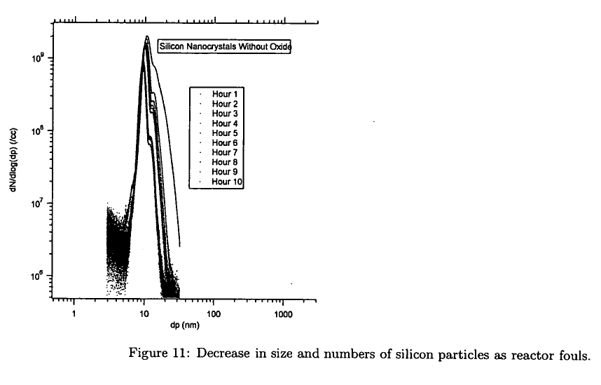

FIG. 11 shows 10 nm particles collected by electrostatic precipitation on a TEM grid that were not sent through a neutralizer. These particles, nearly 10 nm in size, are highly monodisperse, nicely spherical, crystalline and generally deposited as single particles rather than non-coalesced doublets, triplets or fractal agglomerates. Avoiding the relatively long time residence time in a neutralizer prevents significant cold agglomeration. The particles also appear to show a tendency to collect in a 2D hexagonal monolayer array. An inset of the diffraction pattern is included to illustrate particle crystallinity.

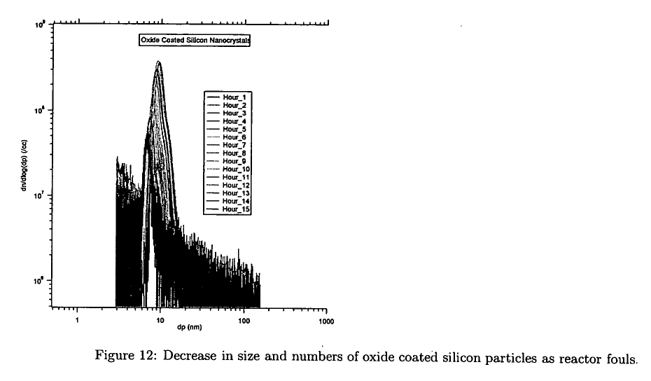

Experiments confirm that for a constant inlet flow rate and silane concentration there is greater agglomeration when using a quenching flow ratio of 5:1 as compared to 7:1 or 10:1. However, little difference is observed between 10 using flow ratios of 7:1 and 10:1. FIG. 12 shows distributions for quenching rates of 5:1, 7:1 and 10:1. Precursor concentration and flow rate were kept constant at 150 ppm SiH₄ in this experiment. Since the number concentration measured is affected by the total flow rate the latter figure shows the concentrations normalized to more clearly illustrate the effect of increased agglomeration. Particle size tended to increase and the distribution broadened when flow rates were altered. Too little flow increases the time for agglomeration. Too much flow and the gas may not reach thermal equilibrium for sufficient time. Exiting particles may possess lower density and lesser mobility, shifting the distribution to larger apparent sizes.

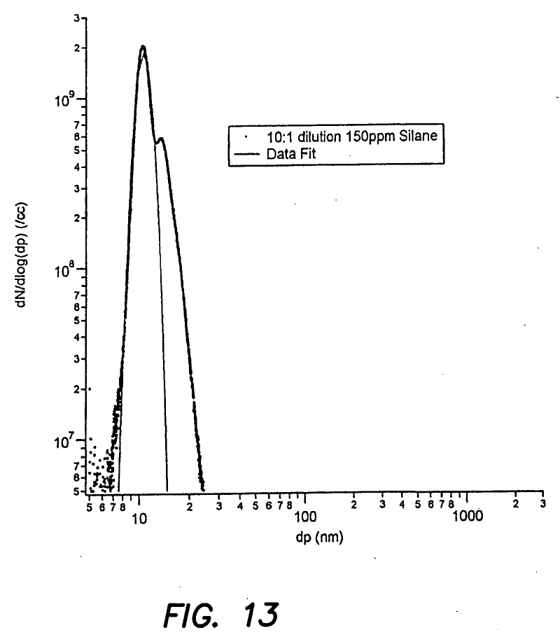

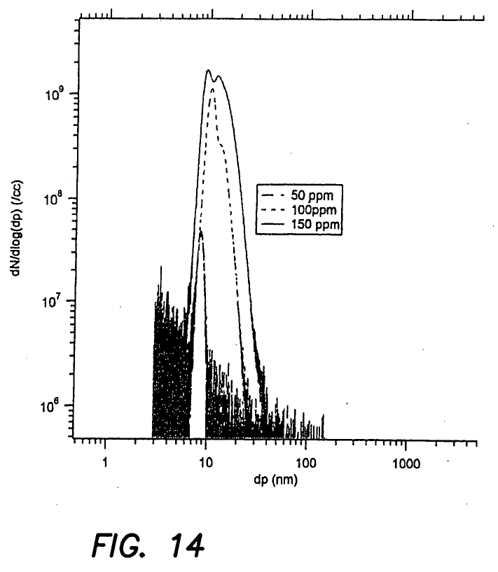

The number of particles produced can be manipulated by varying the concentration of the precursor. As a general trend, the greater the concentration of precursor, the greater the number of particles produced. Under certain operating conditions, particle distributions are highly monodisperse, with a σ_{G} as little as 1.1 as shown in FIG. 13. Increasing the precursor concentration and nucleated particle numbers beyond the agglomeration limits inherent in the geometry of the nucleation or sintering zones will adversely affect the monodispersity of the particle distribution. Too much precursor yields a self preserving aerosol distribution. At intermediate concentrations, the particle distribution is bimodal, with a second peak arising from the monodisperse peak. This second peak dominates as precursor concentration is increased. We attribute this second mode to the formation of doublet particles. Non-densified doublet formation is likely occurring near the end of the densification zone, where the introduction of oxygen turns off surface diffusion or exit cooling slows surface diffusion, giving rise to a lesser mobility particle with a discrete shift from the original distribution. FIG. 14 summarizes these observations with distributions measured from precursor SiH₄ concentrations of 50 ppm, 100 ppm and 150 ppm in a constant flow 10:1 quenching dilution experiment.

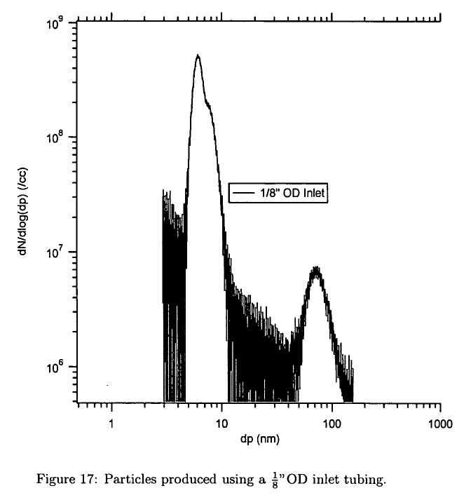

Reducing particle size without significantly altering operating conditions is possible by varying the dimensions and geometry of the inlet tubing where nucleation occurs. FIG. 17 shows the dramatic effect on particle size of using a 1 8″ OD stainless steel inlet tubing. Although smaller tubing fouls more quickly, it can be operated for several hours at production rates in excess of 10⁸/cm³. Recirculation about the end of a square edged nozzle likely accounts for the large-sized particle production. A 7° conical nozzle eliminated the large particle production in a later experiment.

To avoid shifts in characteristic traces of particle distributions from non-coalescent agglomeration within a neutralizer, nitrogen gas was first passed through an 85Kr neutralizer and then mixed with a portion of the reactor product. The equilibrium charge distribution imparted upon the gas within a neutralizer decays upon leaving the vessel, but presumably charge transfer can still occur from gas to particles for a brief time. Nitrogen gas at ratio of 7:1 was mixed with the aerosol stream within 70 ms of leaving the neutralizer. A decay time constant of 700 ms is reported for 90% loss of detectable ions originally at a Boltzmann charge distribution from a 10 milliCurie ²⁴⁰Po Neutralizer.

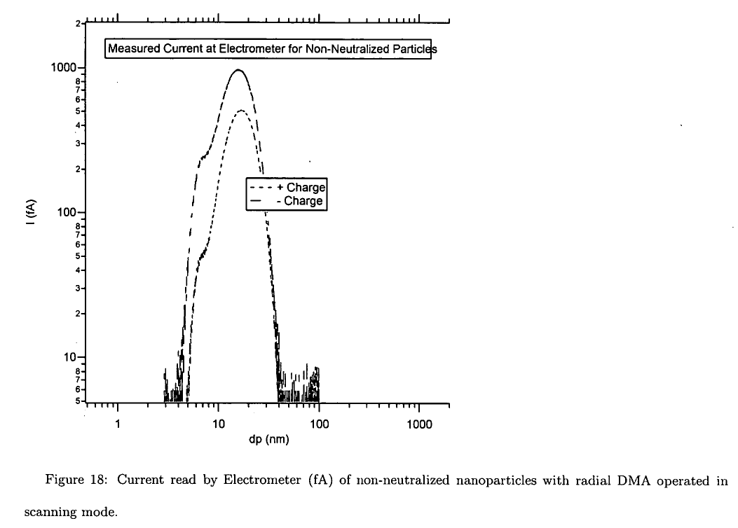

FIG. 18 shows a plot of the measured distributions of particles using varying ratios of pre-neutralized gas. With an increasing volumetric flow of this gas, a shift to smaller particles and greater numbers is seen in the classified distribution. While additional dilution impedes agglomeration, pre-neutralized diluent has a greater effect of increasing the number of charged smaller particles that pass through the electrometer. After careful MFC calibration and correction for dilution, a limiting threshold is reached at dilution values of about 7:1, giving us confidence that the system has reached equilibrium and a known charge distribution has been achieved.

A fraction of the sub-20 nm particles leaving the reactor are charged. The charge carried is a bipolar distribution, with approximately 25% more particles carrying a negative charge than a positive charge, a proportion similar to that predicted by Fuchs for a Boltzmann charge distribution. It was not investigated whether the particles were at the Boltzman charge equilibrium. It is unlikely that thermionic emission of nitrogen at 1000° C. could create this bipolar charge distribution. Charging sources within the apparatus were briefly investigated. The assembly tested negative for radioactive contaminants. Thus it is unlikely that the origin of the bipolar distribution is from radioactive metals or a leaking neutralizer.

Thus, it can now be appreciated that an aerosol reactor 10 incorporating turbulent mixing zones has been demonstrated that achieves high number throughput highly monodisperse crystalline silicon or oxide coated silicon nanoparticles. This reactor is capable, with suitable precursors and additional mixing zones, of producing onion-skin multilayered particles in quantities approaching the needs of ULSI manufacturing. Turbulent mixers within the reactor enhance transport without increasing agglomeration. Particles are found to be highly monodisperse in distribution and consistent in morphology. Particle size is determined by a combination of nucleation rate and residence time within a nucleation zone. This reactor is capable of improvements that can increase its output by a factor of 10-100.

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following claims. For example, notwithstanding the fact that the elements of a claim are set forth below in a certain combination, it must be expressly understood that the invention includes other combinations of fewer, more or different elements, which are disclosed in above even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

The claims are thus to be understood to include what is specifically illustrated and described above, what is conceptionally equivalent, what can be obviously substituted and also what essentially incorporates the essential idea of the invention.

We claim:

1. A method for producing nano-sized particles comprising:
providing reactants in a nucleation and core growth region in a reactor;
heating the reactants to a thermal decomposition temperature to produce a supersaturated vapor that nucleates aerosol particles into corresponding particle cores in the nucleation and core growth region of the reactor during an average residence time in the nucleation and core growth region;
turbulently mixing a preheated diluent into the heated reactants;
flowing the mixed preheated diluent and heated reactants into a core densification region in the reactor to quench particle growth, limit coagulation and provide sufficient thermal energy for densification of the cores of the particles;
turbulently mixing a preheated additional reactant into one or more jets and chemical injection and layer formation region; and
developing the particle cores in the jet and chemical injection and layer formation region.

2. The method of claim 1 where heating the reactants in the nucleation and core growth region of the reactor comprises maintaining the average residence time in the nucleation and core growth region below the characteristic agglomeration time for the number and size of particles desired.

3. The method of claim 1 where heating the reactants in the nucleation and core growth region of the reactor comprises providing particle growth by chemical vapor deposition at the surface of particles or by particle-to-particle collision.

4. The method of claim 1 where turbulently mixing a preheated diluent into the heated reactants comprises diluting particle concentration approximately one order of magnitude or greater to reduce characteristic agglomeration times by the corresponding inverse of the magnitude of the dilution.

5. The method of claim 1 where turbulently mixing a preheated diluent into the heated reactants comprises temporarily maintaining the particles distribution approximately fixed while densification of the particles occurs.

6. The method of claim 1 where turbulently mixing a preheated diluent into the heated reactants comprises injecting the diluent through one or more nozzle flows, such that the dissipation of kinetic energy of the diluent in the nozzle flows generates turbulence, and providing rapid thermal and chemical equilibrium within a path length in the core densification region in the reactor on the order of the reactor diameter.

7. The method of claim 6 where injecting the diluent through one or more nozzles comprises injecting diluent through two nozzles located opposite each other across the reactor.

8. The method of claim 1 where turbulently mixing a preheated diluent into the heated reactants comprises flowing the mixed preheated diluent and heated reactants along a length in the core densification region on the order of 5-10 reactor diameters to allow eddies formed from turbulent mixing effects to dampen.

9. The method of claim 1 where developing the particle in the jet and chemical injection and layer formation region comprises providing reactions which consume particles from the surface inward, adding mass and size to the particle core, or preparing the surface of the particle for further reactions.

10. The method of claim 9 where preparing the surface of the particle for further reactions comprises adding a wetting component for a non-wetting reactant.

11. The method of claim 1 where turbulently mixing a preheated additional reactant into a jet and chemical injection and layer formation region comprises using turbulent mixing to ensure proper pretreatment of surfaces or reaction ignition within a path length in the jet and chemical injection and layer formation region on the order of the reactor diameter.

12. The method of claim 1 further comprising introducing a preheated diluent through a porous or perforated tube located radially around a nucleation zone in the nucleation and core growth region to reduce precursor loss.

13. The method of claim 12 where introducing a preheated diluent through a porous or perforated tube comprises creating a pressure wall which envelops axial flow of the heated reactants in the nucleation and core growth region and accelerating the axial flow to reduce the residence time of the developing nanoparticles.

14. The method of claim 12 where introducing a preheated diluent through a porous or perforated tube comprises limiting the precursor loss entirely to diffusional losses against an incoming flow.

15. The method of claim 12 where introducing a preheated diluent through a porous or perforated tube comprises introducing a preheated diluent through a porosity of the tube of a size such that the diluent passes uniformly into the reactor.

16. The method of claim 1 further comprising confining reactor flow through a coaxial outer annular flow to reduce precursor loss.

17. The method of claim 16 where confining reactor flow through a coaxial outer annular flow to reduce precursor loss comprises introducing a preheated concurrent laminar stream in the nucleation and core growth region at the same average velocity as the precursor containing stream, which introduction limits precursor loss to that which can diffuse across the confinement flow.

18. The method of claim 17 where introducing a preheated concurrent laminar stream in the nucleation and core growth region at the same average velocity as the precursor containing stream comprises flowing the two streams concurrently for less time than the characteristic diffusion time across the annular flow before being first turbulently mixed.

19. The method of claim 1 further comprising sequentially turbulently mixing a plurality preheated additional reactants into a corresponding plurality of jet and chemical injection and layer formation regions and developing the particles in each of the plurality of jet and chemical injection and layer formation regions.

20. The method of claim 19 where turbulently mixing a plurality preheated additional reactants comprises preventing back diffusion of reactants into upstream portions of preceding ones of the plurality of jet and chemical injection and layer formation regions where particles are still developing.

21. The method of claim 1 further comprising sequentially turbulently mixing one or more additional reactants in an unreacted state into a corresponding jet and chemical injection and layer formation region and developing the particles in each of the jet and chemical injection and layer formation regions upon subsequent heating.

22. A reactor for producing nano-sized particles comprising:
a nucleation and core growth region providing a flow of reactants in which the reactants thermally decompose to produce a supersaturated vapor that nucleates aerosol particles into particle cores during an average residence time;
means for turbulently mixing a preheated diluent into the heated reactants;
a core densification region in which the mixed preheated diluent and heated reactants flow and wherein particle growth is quenched, coagulation limited and sufficient thermal energy for densification of the cores of the particles is provided;
means for turbulently mixing a preheated additional reactant; and
a jet and chemical injection and layer formation region for developing the particle cores.

23. The reactor of claim 22 where the average residence time in the nucleation and core growth region is maintained below the characteristic agglomeration time for the number and size of particles desired.

24. The reactor of claim 22 where particle growth by chemical vapor deposition at the surface of particles or by particle-to-particle collision is performed in nucleation and core growth region.

25. The reactor of claim 22 where the means for turbulently mixing a preheated diluent into the heated reactants comprises means for diluting particle concentration approximately one order of magnitude or greater to reduce characteristic agglomeration times by the corresponding inverse of the magnitude of the dilution.

26. The reactor of claim 22 where the means for turbulently mixing a preheated diluent into the heated reactants comprises means for temporarily maintaining the particles distribution approximately fixed while densification of the particles occurs.

27. The reactor of claim 22 where the core densification region has a diameter and where the means for turbulently mixing a preheated diluent into the heated reactants comprises one or more nozzles such that the dissipation of kinetic energy of the diluent in the nozzle flows generates turbulence to provide rapid thermal and chemical equilibrium within a path length in the core densification region on the order of the core densification region diameter.

28. The reactor of claim 27 where injecting the diluent through one or more nozzles comprises injecting diluent through two nozzles located opposite each other across the reactor.

29. The reactor of claim 22 where the core densification region has a diameter and where the means for turbulently mixing a preheated diluent into the heated reactants comprises means for flowing the mixed preheated diluent and heated reactants along a length in the core densification region on the order of 5-10 reactor diameters to allow eddies formed from turbulent mixing effects to dampen.

30. The reactor of claim 22 where reactions are performed in the jet and chemical injection and layer formation region which consume particles from the surface inward, mass and size added to the particle core, or the surface of the particle for further reactions is prepared.

31. The reactor of claim 30 where the surface of the particle for further reactions is prepared in the jet and chemical injection and layer formation region by adding a wetting component for a non-wetting reactant.

32. The reactor of claim 22 where the jet and chemical injection and layer formation region has a diameter and where the means for turbulently mixing a preheated additional reactant into the jet and chemical injection and layer formation region comprises means for using turbulent mixing to ensure proper pretreatment of surfaces or reaction ignition within a path length in the jet and chemical injection and layer formation region on the order of the diameter of the jet and chemical injection and layer formation region.

33. The reactor of claim 22 further comprising a porous or perforated tube located radially around a nucleation zone in the nucleation and core growth region for introducing a preheated diluent to reduce precursor loss.

34. The reactor of claim 33 where the porous or perforated tube is arranged and configured to create a pressure wall which envelops axial flow of the heated reactants in the nucleation and core growth region and to accelerate the axial flow to reduce the residence time of the developing nanoparticles.

35. The reactor of claim 33 where the porous or perforated tube limits the precursor loss entirely to diffusional losses against an incoming flow.

36. The reactor of claim 33 where the porous or perforated tube introduces a preheated diluent through a porosity of the tube of a size such that the diluent passes uniformly into the nucleation and core growth region.

37. The reactor of claim 22 further comprising means for confining reactor flow through a coaxial outer annular flow to reduce precursor loss.

38. The reactor of claim 37 where the means for confining reactor flow through a coaxial outer annular flow to reduce precursor loss comprises means for introducing a preheated concurrent laminar stream in the nucleation and core growth region at the same average velocity as the precursor containing stream, which introduction limits precursor loss to that which can diffuse across the confinement flow.

39. The reactor of claim 38 where the means for introducing a preheated concurrent laminar stream in the nucleation and core growth region at the same average velocity as the precursor containing stream comprises means for flowing the two streams concurrently for less time than the characteristic diffusion time across the annular flow before being first turbulently mixed.

40. The reactor of claim 22 further comprising means for sequentially turbulently mixing a plurality preheated additional reactants into a corresponding plurality of jet and chemical injection and layer formation regions and for developing the particles in each of the plurality of jet and chemical injection and layer formation regions.

41. The reactor of claim 40 where the means for turbulently mixing a plurality preheated additional reactants comprises means for preventing back diffusion of reactants into upstream portions of preceding ones of the plurality of jet and chemical injection and layer formation regions where particles are still developing.
